(19) United States
(12) Patent Application Publication
(10) Pub. No.: US 2024/0357809 A1
(43) Pub. Date: Oct. 24, 2024

(54) SUPPORT STRUCTURES FOR TIER DEFLECTION IN A MEMORY SYSTEM

(71) Applicant: Micron Technology, Inc., Boise, ID (US)

(72) Inventors: Zeyar Lin Aung, Boise, ID (US); Kaiming Luo, Singapore (SG); Saurabh Jagdishbhai Kasodariya, Hyderabad (IN); Sumeet C. Pandey, Meridian, ID (US); Brittany L. Kohoutek, Boise, ID (US); Yuwei Ma, Singapore (SG); Kyle A. Ritter, Boise, ID (US)

(21) Appl. No.: 18/637,129

(22) Filed: Apr. 16, 2024

Related U.S. Application Data
(60) Provisional application No. 63/497,928, filed on Apr. 24, 2023.

(51) Int. Cl. H10B 43/20

(52) U.S. Cl. CPC H10B 43/20

(57) ABSTRACT

Methods, systems, and devices for support structures for tier deflection in a memory system are described. The memory system may include a word line contact that extends through a stack of materials and lands on a tier of a word line. The word line contact may be between four support structures that form a diamond around the word line contact. Two support structures that form opposite vertices of the diamond may align centrally with the word line contact in a lateral direction and two other support structures that form opposite vertices of the diamond may align centrally with the word line contact in a longitudinal direction.

### CROSS REFERENCE

The present application for patent claims priority to U.S. Patent Application No. 63/497,928 by Aung et al., entitled “SUPPORT STRUCTURES FOR TIER DEFLECTION IN A MEMORY SYSTEM,” filed Apr. 24, 2023, which is assigned to the assignee hereof, and which is expressly incorporated by reference in its entirety herein.

### TECHNICAL FIELD

The following relates to one or more systems for memory, including support structures for tier deflection in a memory system stack.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a memory system with support structures for tier deflection in accordance with examples as disclosed herein.

FIG. 2 illustrates an example of a memory system stack that has support structures for tier deflection in accordance with examples as disclosed herein.

FIG. 3 illustrates an example of a memory system stack that has support structures for tier deflection in accordance with examples as disclosed herein.

FIG. 4 illustrates an example of a memory system stack that has support structures for tier deflection in accordance with examples as disclosed herein.

### DETAILED DESCRIPTION

In some memory systems, a stack of materials may include tiers (e.g., layers) of conductive material, which may form the word lines for different memory cells, and tiers (e.g., layers) of dielectric materials (e.g., to prevent shorts between the word lines). Word line contacts, in the form of conductive pillars, may be used to connect the word lines in the stack with array circuitry (e.g., word line drivers). For example, the word line contacts may extend through the stack and land on (e.g., connect to) different word lines in the stack. In some case, the tiers of conductive material that form the word lines may deflect (e.g., sag, deform, become less planar) during manufacturing, which may negatively impact the functionality of the memory system.

According to the present disclosure, deflection of word line tiers during manufacturing may be reduced by placing support structures in a diamond pattern around the word line contacts. For example, a given word line contact may be surrounded by four support structures that form a diamond around the word line contact. Two support structures that form opposite vertices of the diamond may align (e.g., centrally) with the word line contact in a lateral direction and two other support structures that form opposite vertices of the diamond may align (e.g., centrally) with the word line contact in a longitudinal direction. Thus, the support structure may be substantially or, in some examples exactly, at the center of the diamond formation, which may reduce deflection of the corresponding word line tier during manufacturing. Memory systems with reduced deflections in word line tiers may have improved functionality (e.g., due to reduced shorts between word lines) relative to memory systems with larger deflections.

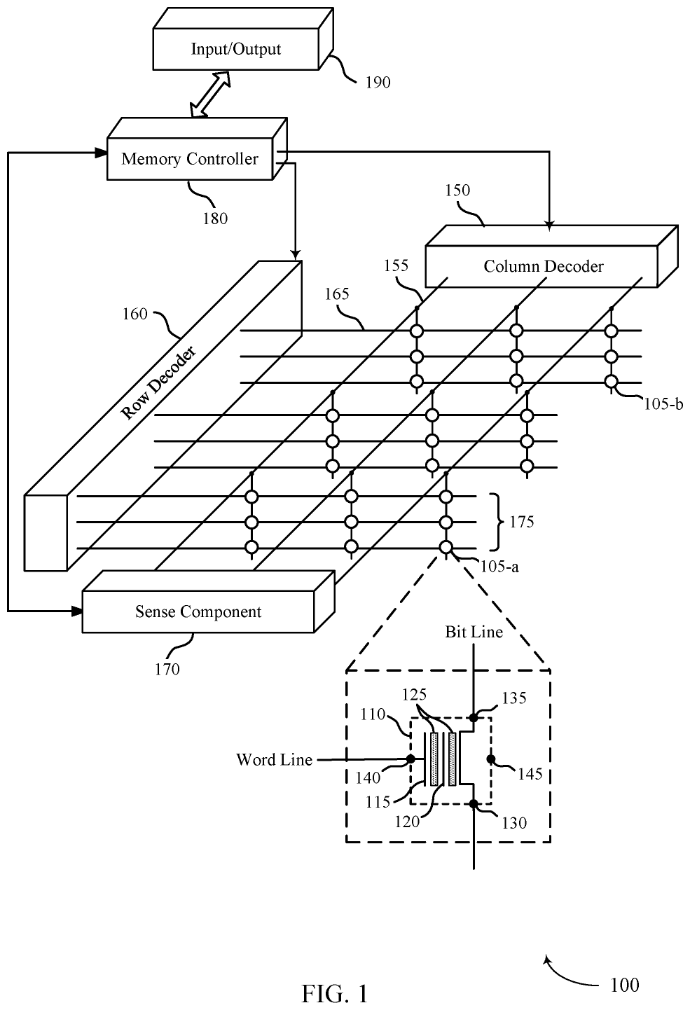

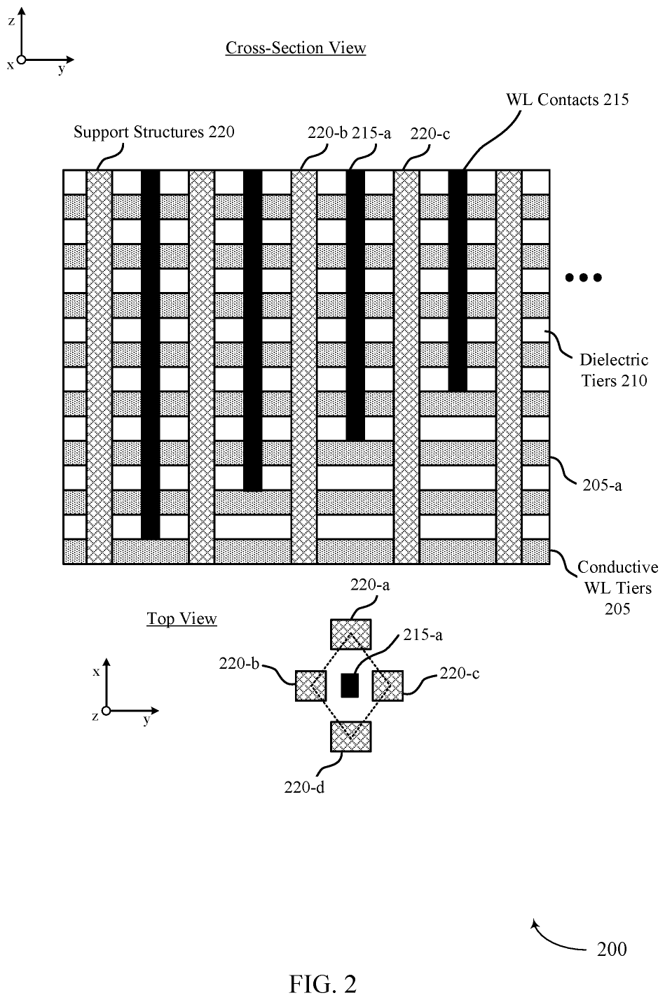

Features of the disclosure are initially described in the context of systems, devices, and circuits with reference to FIG. 1. Features of the disclosure are described in the context of memory system stacks with reference to FIGS. 2 through 4.

FIG. 1 illustrates an example of a memory device 100 that supports support structures for tier deflection in a memory system stack in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105.

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In some examples, the word lines 165 may be in the form of conductive (e.g., metal) tiers that form layers of a stack. The conductive tiers may be separated by (e.g., interspersed between) dielectric tiers (e.g., to prevent shorts between the word lines 165) and may be coupled with various components (e.g., word line drivers) via word line contacts that extend through the stack and land on different conductive tiers. During manufacturing, the conductive tiers of the word lines 165 may deflect (e.g., due to the thinness of the conductive tiers) which may negatively impact the functionality of the memory system (e.g., by resulting in shorts between word lines 165). Accordingly, the techniques described herein, the deflection of word line tiers during manufacturing may be reduced by placing support structures around the word line contacts in a diamond pattern.

FIG. 2 illustrates an example of a stack 200 of a memory system that has support structures for tier deflection in accordance with examples as disclosed herein. The stack 200 may include alternating tiers (e.g., layers) of different materials in the z-direction. For example, the stack 200 may include conductive WL tiers 205 separated by dielectric tiers 210. The conductive WL tiers 205 may be coupled with one or more various components (e.g., word line drivers) above and/or below the stack 200 via word line contacts 215 that are in the form of conductive pillars that extend through the stack 200 in the z-direction. Each word line contact 215 may land on (e.g., connect to, couple with) a respective conductive WL tier 205. For example, word line contact 215-a may land on conductive word line tier 205-a.

In some examples, the conductive WL tiers 205 may include a metal material such as tungsten and the dielectric tiers 210 may include an insulative material such as oxide. It should be appreciated that the word line contacts 215 may be at least partially surrounded by a dielectric material (not shown) to prevent shorts between the landing conductive WL tier 205 and the other conductive WL tiers through which the word line contacts extend.

During manufacturing, the conductive WL tiers 205 may be susceptible to deflecting (e.g., sagging) for example in the z-direction, which may negatively impact the functionality of the memory system that includes the stack 200. To reduce such deflections, the stack 200 may include support structures 220 that extend through the stack 200 for example in the z-direction. In some examples, the support structures may be through-silicon-vias (TSVs) that are filled with a support material (e.g., tungsten, oxide). Thus, in some examples, the support structures may be referred to as support TSVs, filled TSVs, or other suitable terminology. Unlike other vias that may be in or associated with the stack 200, the support structures 220 may be configured to at least partially structurally support the stack 200 and may not conduct electrical signals between components.

The support structures 220 may be arranged (e.g., configured) in a diamond pattern that reduces (e.g., relative to other arrangements) the deflections of the conductive WL tiers 205 during manufacturing. For example, as shown in the top view, the word line contact 215-a may be laterally and longitudinally flanked by support structures 220-a, 220-b, 220-c, and 220-d. Put another way, the support structures 220 may be symmetrically positioned around the word line contact 215-a in the y-direction and the x-direction. For viewing case, the support structure 220-a and the support structure 220-d are not shown in the cross-section view.

The support structure 220-a and the support structure 220-d may be a pair of support structures that are arranged to form opposite vertices of the diamond formation, and the support structure 220-b and the support structure 220-c may be a pair of support structures that are arranged to form opposite vertices of the diamond formation. As shown, the support structure 220-a and the support structure 220-d may be centrally aligned with the word line contact 215-a in the y-direction (e.g., the centers of the supports structures 220-a, 220-d may align with the center of the word line contact 215-a in the y-direction). Similarly, the support structure 220-b and the support structure 220-c may be centrally aligned with the word line contact 215-a in the x-direction (e.g., the centers of the supports structures 220-b, 220-c may align with the center of the word line contact 215-a in the x-direction).

Centering the word line contacts 215 within the diamond formations of the support structures 215 may provide additional support, relative to other formations, to the conductive WL tiers 210 during manufacturing. For example, consistently aligning the centers of the word line contacts 215 with respective pairs of lateral support structures in the y-direction may provide additional support relative to formations that offset the centers of the word line contacts 215 with lateral support structures. Thus, stacks of materials that use the diamond pattern for support structures may have less severe deflection relative to stacks of materials that use other arrangements, which in turn may reduce unintended, performance-degrading shorts (e.g., connections) between tiers (e.g., conductive WL tiers).

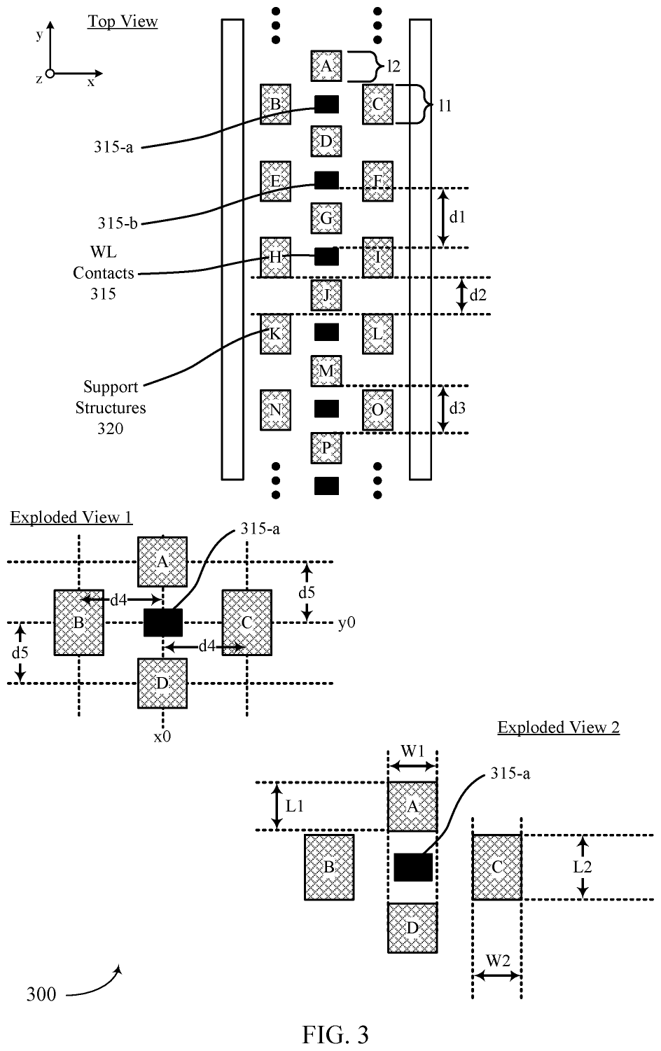

FIG. 3 illustrates an example of a stack 300 of a memory system that has support structures for tier deflection in accordance with examples as disclosed herein. The stack 300 may be an example of a stack 200 as described with reference to FIG. 2. So, the stack 300 may include tiers of materials (not shown), such as alternating conductive WL tiers and dielectric tiers. The stack 300 may include word line contacts 315 and support structures 320. The word line contacts 315 and the support structures 320 may extend through the tiers of the stack 300 in the z-direction as shown in FIG. 2. The word line contacts 315 may be centered within diamond formations of the support structures 320, which may help decrease deflection of the conductive WL tiers during manufacturing, among other advantages. In some examples, the word line contacts 315 and the support structures 320 may have a rectangular shape in the x-y plane.

The word line contacts 315 may be spaced (e.g., interspersed, distributed) along a line that extends in the y-direction. In some examples, the word line contacts 315 may be evenly spaced along the line such that the distance between different adjacent word line contacts 315 is consistent (e.g., the same length). For instance, the distance in the y-direction between adjacent word line contacts 315 may be distance d1.

The center of a word line contact may be aligned with a pair of support structures in the x-direction and may be aligned with a pair of support structures in the y-direction. For instance, the word line contact 315-a, which may be disposed between the support structure A and the support structure D in the y-direction, may have a center that is aligned with respective centers of the support structure A and the support structure D in the x-direction. As shown in Exploded View 1, the center of the word line contact 315-a, the center of the support structure A, and the center of the support structure D may each be at position x0 in the x-direction. In some examples, the pair of support structures A and D may be equidistant from word line contact 315-a in the y-direction.

Additionally, the word line contact 315-a, which may be disposed between the support structure B and the support structure C in the x-direction, may have a center that is aligned with the respective centers of the support structure B and the support structure C in the y-direction. As shown in Exploded View 1, the center of the word line contact 315-a, the center of the support structure A, and the center of the support structure D may each be at position y0 in the y-direction. In some examples, the pair of support structures B and C may be equidistance from the word line contact 315-a in the x-direction.

Aligning the support structures 320 with the word line contacts 315 as illustrated in FIG. 3 may, among other benefits, ensure that the support structures 320 overlap with the word line contacts 315 in the x-direction and the y-direction, which may enhance the support provided by the support structures 320 relative to other arrangements.

In some examples, the support structures 320 that align with the word line contacts 315 in the x-direction (e.g., support structures A, D, G, J, M, P) may be referred to as inner support structures and the support structures 320 that align with the word line contacts 315 in the y-direction (e.g., support structures B, C, E, F, H, I, K, L, N, O) may be referred to as outer support structures. A combination of inner support structures and outer support structures may form a diamond formation around a word line contact 315. In some examples, the diamond formations for two adjacent word line contacts 315 may share an inner support structure. For example, the lower inner support structure for word line contact 315-a (e.g., the support structure D) may be the upper inner support structure word line contact 315-b.

The support structures 320 may be arranged in diamond formations that, collectively, form three lines of support structures 320 that extend in the y-direction. The support structures 320 in a line may be evenly spaced along the line such that the distance between different adjacent support structures 320 is consistent (e.g., the same length). For example, the distance in the y-direction between adjacent support structures in the left-most line (e.g., outer support structures B, E, H, K, and N) may be distance d2, which may also be the distance in the y-direction between adjacent support structures in the right-most line (e.g., outer support structures C, F, I, L, and O). The distance in the in the y-direction between adjacent support structures in the middle line (e.g., inner support structures A, D, G, J, M, P) may be distance d3.

Evenly spacing the support structures as described herein may simplify the manufacturing process and enable compliance with manufacturing tolerances, among other benefits. In some examples, the distance d1 may be greater than the distance d3 which may be greater than the distance d2. In some examples, the distance d2 may be between 5 μm and 11 μm.

In some examples, a word line contact 315 may be equidistant (in the x-direction) from the outer support structures of the surrounding diamond formation. For example, as shown in Exploded View 1, the distance (in the x-direction) between the center of the support structure B and the center of the word line contact 315-a may be distance d4. And the distance (in the x-direction) between the center of the support structure C and the center of the word line contact 315-a may also be distance d4. Similarly, a word line contact 315 may be equidistant (in the y-direction) from the inner support structures of the surrounding diamond formation. For example, as shown in Exploded View 1, the distance (in the y-direction) between the center of the support structure A and the center of the word line contact 315-a may be distance d5. And the distance (in the y-direction) between the center of the support structure D and the center of the word line contact 315-a may also be distance d5.

In some examples, the sizes of the outer support structures may be different than the sizes of the inner support structures, which may further help reduce tier deflection. For instance, as shown in Exploded View 2, the length (in the y-direction) of the inner support structures for word line contact 315-a may be length L1 and the length (in the y-direction) of the outer support structures for word line contact 315-a may be length L2, and length L2 may be greater than length L1. The width (in the x-direction) of the inner support structures for word line contact 315-a may be width W1 and the width (in the x-direction) of the outer support structures for word line contact 315-a may be width W2, where width W1 and width W2 may be the same or different. In some examples, the dimensions (e.g., length, width) of the outer support structures may vary slightly (e.g., by 5-10%) with the depth of the associated word line tier. However, the length to width ratio (e.g., 4:3) of the outer support structures (e.g., length/width) may be the same (e.g., ˜1.33), and the lengths of the outer support structures may be greater than the length of the inner support structures.

Thus, the word line contacts 315 may be centered within the diamond formations of the support structures 320, which may reduce deflection of underlying word line tiers during manufacturing. Deflection reduction may in turn improve the functionality of a memory device that includes the stack 300.

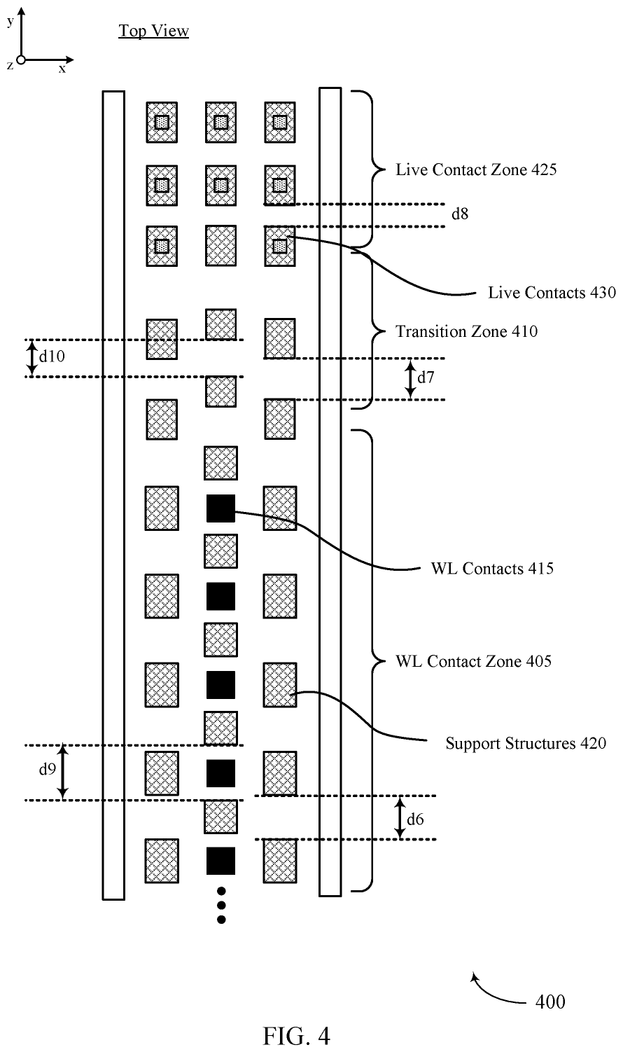

FIG. 4 illustrates an example of a stack 400 of a memory system that has support structures for tier deflection in accordance with examples as disclosed herein. The stack 400 may be an example of aspects of a stack 200 or a stack 300 as described with reference to FIG. 2 and FIG. 3, respectively. For example, the stack 400 may include WL contact zone 405, which may be an example of the stack 200 or the stack 300. So, the stack 400 may include tiers of materials (not shown), such as alternating conductive WL tiers and dielectric tiers. The stack 400 may also include transition zone 410 and live contact zone 425.

The stack 400 may include word line contacts 415, support structures 420, and live contacts 430. The word line contacts 415, the support structures 420, and the live contacts 430 may extend through the tiers of the stack 300 in the z-direction as shown in FIG. 2. Each word line contact 415 may extend a different length into the stack 400 and land on a respective (different) word line tier. The support structures 420 may extend a same length through the stack and may be electrically isolated from the word line tiers. The live contacts 430 may extend through the stack and may electrically couple array circuitry above the stack 400 with array circuitry below the stack 400. In some examples, the live contacts 430 may be vias (e.g., TSVs).

In the WL contact zone, the word line contacts 415 may be centered within diamond formations of the support structures 420, which may help decrease deflection of the conductive WL tiers during manufacturing. The transition zone 410 may include support structures 420 and may omit WL contacts 415 and live contacts 430. The distance (in the y-direction) between adjacent outer support structures 420 may be the same in the WL contact zone and may be different in the transition zone 410. For example, the distance (in the y-direction) between adjacent outer support structures 420 may be distance d6 in the WL contact zone and may be distance d7 in the transition zone 410. The live contact zone 425 may include live contacts 430, which may have a smaller spacing in the y-direction relative to the outer support structures 420. For example, the distance (in the y-direction) between adjacent live contacts 430 may be distance d8, which may be smaller than distance d7.

The distance (in the y-direction) between adjacent inner support structures 420 may be the same in the WL contact zone and may be different in the transition zone 410. For example, the distance (in the y-direction) between adjacent inner support structures 420 may be distance d9 in the WL contact zone and may be distance d10 in the transition zone 410. In some examples, the distance d9 may be greater than the distance d10 (e.g., so that adequate spacing is maintained between the WL contacts 415 and the inner support structures 420 in the WL contact zone).

Thus, the WL contact zone 405 may include word line contacts 415 at the center of diamond-formation support structures 420 and may be arranged differently than the transition zone 410 and the live contact zone 425.

It should be noted that the described designs include possible implementations, and that the components may be rearranged or otherwise modified and that other implementations are possible. Further, portions from two or more of the designs may be combined.

An apparatus is described. The following provides an overview of aspects of the apparatus as described herein:
Aspect 1: An apparatus, including: a set of stacked materials including alternating tiers of dielectric material and tiers of conductive material, the tiers of conductive material including word lines of memory cells; conductive pillars including word line contacts disposed vertically through the set of stacked materials and each coupled with a respective tier of the tiers of conductive material, the word line contacts arranged in a line that extends in a first direction; and support structures disposed vertically through the set of stacked materials and arranged in a diamond formation, where a first pair of support structures at opposite vertices of the diamond formation are aligned with a center of a word line contact in the first direction and a second pair of support structures at opposite vertices of the diamond formation are aligned with the center of the word line contact in a second direction that is orthogonal to the first direction.
Aspect 2: The apparatus of aspect 1, where each support structure in the first pair of support structures has a first length in the first direction and each support structure in the second pair of support structures has a second length in the first direction that is greater than the first length.
Aspect 3: The apparatus of aspect 2, where each support structure in the first pair of support structures and each support structure in the second pair of support structures has a same width in the second direction.
Aspect 4: The apparatus of any of aspects 1 through 3, where the word line contact is disposed between the first pair of support structures in the first direction.
Aspect 5: The apparatus of aspect 4, where the word line contact is equidistant from the first pair of support structures in the first direction.
Aspect 6: The apparatus of any of aspects 1 through 5, where the word line contact is disposed between the second pair of support structures in the second direction.
Aspect 7: The apparatus of aspect 6, where the word line contact is equidistant from the second pair of support structures in the second direction.
Aspect 8: The apparatus of any of aspects 1 through 7, where the word line contacts are evenly spaced from each other in the first direction.
Aspect 9: The apparatus of any of aspects 1 through 8, where the word line contact is disposed between the first pair of support structures in the first direction and disposed between the second pair of support structures in the second direction.
Aspect 10: The apparatus of any of aspects 1 through 9, where the first pair of support structures is disposed between the second pair of support structures in the second direction.

An apparatus is described. The following provides an overview of aspects of the apparatus as described herein:
Aspect 11: An apparatus, including: a stack of materials with conductive tiers that include word lines of memory cells; conductive pillars including word line contacts that extend through the stack of materials in a first direction and that each connect with a respective word line of the word lines, the word line contacts arranged in a line that extends in a second direction that is orthogonal to the first direction; and pairs of support structures that extend through the stack of materials in the first direction, where each word line contact is disposed between a respective pair of support structures that are aligned with the center of that respective word line contact in a third direction orthogonal to the second direction.
Aspect 12: The apparatus of aspect 11, further including: additional pairs of support structures that extend through the stack of materials in the first direction, where each word line contact is disposed between a respective additional pair of support structures, where the respective additional pair of support structures are aligned with the center of that respective word line contact in the second direction.
Aspect 13: The apparatus of aspect 12, wherein each support structure in one of the additional pairs of support structures for a word line contact has a first length in the second direction, and wherein each support structure in one of the pairs of support structures for the word line contact has a second length in the second direction that is greater than the first length.
Aspect 14: The apparatus of aspect 13, where each support structure in the pairs of support structures has a width in the third direction that is less than second length.
Aspect 15: The apparatus of any of aspects 11 through 14, where each word line contact is equidistant from the respective pair of support structures in the third direction.
Aspect 16: The apparatus of any of aspects 11 through 15, where the pairs of support structures include through-silicon-vias filled with tungsten, oxide, or both.
Aspect 17: The apparatus of any of aspects 11 through 16, where the conductive tiers are separated by dielectric tiers.

An apparatus is described. The following provides an overview of aspects of the apparatus as described herein:
Aspect 18: An apparatus, including: a conductive pillar including a word line contact that extends through a stack of materials in a first direction and that connects with a respective word line in the stack of materials; a first pair of support structures including support structures that each extend through the stack of materials in the first direction and that each have a first length in a second direction that is orthogonal to the first direction, where the word line contact is disposed between the first pair of support structures in the second direction; and a second pair of support structures including support structures that each extend through the stack of materials in the first direction and that each have a second length in the second direction that is greater than the first length of the first pair of support structures, where the word line contact is disposed between the second pair of support structures in a third direction that is orthogonal to the second direction and the center of the word line contact is aligned with the second pair of support structures in the second direction.
Aspect 19: The apparatus of aspect 18, where center of the word line contact is aligned with the first pair of support structures in the third direction.
Aspect 20: The apparatus of any of aspects 18 through 19, where the word line contact and the first pair of support structures are disposed between the second pair of support structures in the third direction, and the first pair of support structures and the second pair of support structures are arranged in a diamond formation.
Aspect 21: The apparatus of any of aspects 18 through 20, where the word line contact is centered between the first pair of support structures in the second direction.
Aspect 22: The apparatus of any of aspects 18 through 21, where the word line contact is centered between the second pair of support structures in the third direction.
Aspect 23: The apparatus of any of aspects 18 through 22, where the word line contact is equidistant from the first pair of support structures in the second direction, and the word line contact is equidistant from the second pair of support structures in the third direction.
Aspect 24: The apparatus of any of aspects 18 through 23, further including: a third pair of support structures including support structures that each extend through the stack of materials in the first direction, where a second word line contact is disposed between the first pair of support structures in the second direction, and where the third pair of support structures shares a support structure with the first pair of support structures.
Aspect 25: The apparatus of aspect 24, further including: a fourth pair of support structures including support structures that each extend through the stack of materials in the first direction, where the second word line contact is disposed between the second pair of support structures in the third direction, and where the fourth pair of support structures are aligned with the center of the second word line contact in the second direction.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a set of stacked materials comprising alternating tiers of dielectric material and tiers of conductive material, the tiers of conductive material comprising word lines of memory cells;
conductive pillars comprising word line contacts disposed vertically through the set of stacked materials and each coupled with a respective tier of the tiers of conductive material, the word line contacts arranged in a line that extends in a first direction; and
support structures disposed vertically through the set of stacked materials and arranged in a diamond formation, wherein a first pair of support structures at opposite vertices of the diamond formation are aligned with a center of a word line contact in the first direction and a second pair of support structures at opposite vertices of the diamond formation are aligned with the center of the word line contact in a second direction that is orthogonal to the first direction.

2. The apparatus of claim 1, wherein each support structure in the first pair of support structures has a first length in the first direction and each support structure in the second pair of support structures has a second length in the first direction that is greater than the first length.

3. The apparatus of claim 2, wherein each support structure in the first pair of support structures and each support structure in the second pair of support structures has a same width in the second direction.

4. The apparatus of claim 1, wherein the word line contact is disposed between the first pair of support structures in the first direction.

5. The apparatus of claim 4, wherein the word line contact is equidistant from the first pair of support structures in the first direction.

6. The apparatus of claim 1, wherein the word line contact is disposed between the second pair of support structures in the second direction.

7. The apparatus of claim 6, wherein the word line contact is equidistant from the second pair of support structures in the second direction.

8. The apparatus of claim 1, wherein the word line contacts are evenly spaced from each other in the first direction.

9. The apparatus of claim 1, wherein the word line contact is disposed between the first pair of support structures in the first direction and disposed between the second pair of support structures in the second direction.

10. The apparatus of claim 1, wherein the first pair of support structures is disposed between the second pair of support structures in the second direction.

11. An apparatus, comprising:
a stack of materials with conductive tiers that comprise word lines of memory cells;
conductive pillars comprising word line contacts that extend through the stack of materials in a first direction and that each connect with a respective word line of the word lines, the word line contacts arranged in a line that extends in a second direction that is orthogonal to the first direction; and
pairs of support structures that extend through the stack of materials in the first direction, wherein each word line contact is disposed between a respective pair of support structures that are aligned with the center of that respective word line contact in a third direction orthogonal to the second direction.

12. The apparatus of claim 11, further comprising:
additional pairs of support structures that extend through the stack of materials in the first direction, wherein each word line contact is disposed between a respective additional pair of support structures, wherein the respective additional pair of support structures are aligned with the center of that respective word line contact in the second direction.

13. The apparatus of claim 12, wherein each support structure in one of the additional pairs of support structures for a word line contact has a first length in the second direction, and wherein each support structure in one of the pairs of support structures for the word line contact has a second length in the second direction that is greater than the first length.

14. The apparatus of claim 13, wherein each support structure in the pairs of support structures has a width in the third direction that is less than second length.

15. The apparatus of claim 11, wherein each word line contact is equidistant from the respective pair of support structures in the third direction.

16. The apparatus of claim 11, wherein the pairs of support structures comprise through-silicon-vias filled with tungsten, oxide, or both.

17. The apparatus of claim 11, wherein the conductive tiers are separated by dielectric tiers.

18. An apparatus, comprising:
a conductive pillar comprising a word line contact that extends through a stack of materials in a first direction and that connects with a respective word line in the stack of materials;
a first pair of support structures comprising support structures that each extend through the stack of materials in the first direction and that each have a first length in a second direction that is orthogonal to the first direction, wherein the word line contact is disposed between the first pair of support structures in the second direction; and
a second pair of support structures comprising support structures that each extend through the stack of materials in the first direction and that each have a second length in the second direction that is greater than the first length of the first pair of support structures, wherein the word line contact is disposed between the second pair of support structures in a third direction that is orthogonal to the second direction and the center of the word line contact is aligned with the second pair of support structures in the second direction.

19. The apparatus of claim 18, wherein the center of the word line contact is aligned with the first pair of support structures in the third direction.

20. The apparatus of claim 18, wherein the word line contact and the first pair of support structures are disposed between the second pair of support structures in the third direction, and wherein the first pair of support structures and the second pair of support structures are arranged in a diamond formation.
